(19) United States
(12) Patent Application Publication
(10) Pub. No.: US 2026/0191115 A1
(43) Pub. Date: Jul. 2, 2026

(54) LEADFRAME-BASED ISOLATION COMPONENTS

(71) Applicant: TEXAS INSTRUMENTS INCORPORATED, DALLAS, TX (US)

(72) Inventors: Vijaylaxmi Khanolkar, Pune (IN); Sreeram Nasum S, Bangalore (IN); Suvadip Banerjee, Bangalore (IN); Nicola Bertoni, Freising (DE); Giacomo Calabrese, Freising (DE)

(21) Appl. No.: 19/002,674

(22) Filed: Dec. 26, 2024

(51) Int. Cl. H01L 23/498; H01L 21/48; H01L 25/00; H01L 25/18; H10D 1/20

(52) U.S. Cl. CPC H10W 90/701; H10D 1/20; H10W 70/05; H10W 70/65; H10W 90/00

(57) ABSTRACT

An electronic device includes a leadframe and one or more substrate assemblies attached to the leadframe. The one or more substrate assemblies include a first substrate layer and a second substrate layer attached to the first substrate layer. A first electronic component is formed in one or both of the first substrate layer and the second substrate layer. A second electronic component is formed in one or both of the first substrate layer and the second substrate layer such that the first electronic component and the second electronic component are interdigitated. One or more dies are attached to the leadframe and are electrically connected to the substrate assembly via wire bonds. A mold compound encapsulates the one or more substrate assemblies and the one or more dies.

### TECHNICAL FIELD

The present disclosure relates to electronic devices, and more specifically to a leadframe-based isolation components for use in integrated circuits.

### BACKGROUND

Leaded or leadless integrated circuit (IC) packages (e.g., SOIC, LGA, QFN, etc.) may include integrated isolation components (e.g., transformers, capacitors, filters, etc.) to create multi-chip modules (MCM's). MCM's include multiple dies and multiple integrated isolation components. The integrated isolation components are fabricated using a multiple layer (e.g., 6-layer) laminate topology. The multiple layer laminate configuration provides sufficient power transfer while simultaneously providing the required isolation. The multiple layer laminate configuration, however, significantly contributes to the overall package size and cost.

### SUMMARY

In a described example, an electronic device includes a leadframe and a substrate assembly attached to the leadframe, where the substrate assembly includes a first substrate layer and a second substrate layer. An electronic component is formed in at least one or both of the first substrate layer and the second substrate layer. A die is attached to the leadframe and a mold compound encapsulates the substrate assembly and the die.

In another described example, a substrate assembly includes a first substrate layer and a second substrate layer attached to the first substrate layer. A first electronic component is formed in one or both of the first substrate layer and the second substrate layer. A second electronic component is formed in one or both of the first substrate layer and the second substrate layer such that the first electronic component and the second electronic component are interdigitated.

In still another described example, a method includes depositing a first metal layer on a carrier and forming a first dielectric layer over the first metal layer. A second metal layer is formed on the first dielectric layer and a second dielectric layer is formed over the second metal layer. The first and second dielectric layers are from the carrier.

In still another describe example, a method includes attaching at least one substrate assembly to contact pads of a leadframe and attaching at least one die to die attach pads of the leadframe. Wire bonds are attached from the at least one die to the at least one substrate assembly and to inner leads of the leadframe. A mold compound is formed over the one ore more substrate assemblies, the one or more dies, the wire bonds, and the inner leads.

### BRIEF DESCRIPTION OF THE DRAWINGS

FIG. 1A and B are top perspective and cross-sectional views respectively of an example electronic device.

FIGS. 1C and 1D are cross-sectional views of other example electronic devices.

FIG. 2 is a top perspective view of an example substrate assembly.

FIG. 3 is a block diagram flow chart explaining a fabrication process of an example electronic device.

FIG. 4A illustrates a cross-sectional view of a metal carrier in the early stages of fabrication of an example substrate assembly

FIG. 4B illustrates a cross-sectional view of the metal carrier of FIG. 4A after undergoing formation and patterning of a first photoresist material layer on the metal carrier.

FIG. 4C illustrates a cross-sectional view of the substrate assembly of FIG. 4B after undergoing a first plating process.

FIG. 4D illustrates a cross-sectional view of the substrate assembly of FIG. 4C after undergoing removal of the first photoresist material layer.

FIG. 4E illustrates a cross-sectional view of the substrate assembly of FIG. 4D after undergoing formation of a first dielectric layer via a compression molding process.

FIG. 4F illustrates a cross-sectional view of the substrate assembly of FIG. 4E after undergoing a back grinding process to grind a portion of the first dielectric layer.

FIG. 4G illustrates a cross-sectional view of the substrate assembly of FIG. 4F after undergoing formation and patterning of a second photoresist material layer.

FIG. 4H illustrates a cross-sectional view of the substrate assembly of FIG. 4G after undergoing a second plating process.

FIG. 4I illustrates a cross-sectional view of the substrate assembly of FIG. 4H after undergoing removal of the second photoresist material layer.

FIG. 4J illustrates a cross-sectional view of the substrate assembly of FIG. 4I after undergoing formation of a second dielectric layer via a compression molding process.

FIG. 4K illustrates a cross-sectional view of the substrate assembly of FIG. 4J after undergoing a back grinding process to grind a portion of the second dielectric layer.

FIG. 4L illustrates a cross sectional view of the substrate assembly of FIG. 4K after removal of the metal carrier.

FIG. 4M illustrates a cross-sectional view of the substrate assembly of FIG. 4L after being flipped 180°.

FIG. 5 is a block diagram flow chart explaining an assembly process of an example electronic device.

FIG. 6A is a top view of a leadframe in the early stages of assembly of an example electronic device.

FIG. 6B is a top view of the electronic device of FIG. 6A after attachment of a substrate assembly to contact pads of the leadframe.

FIG. 6C is a top view of the electronic device of FIG. 6B after attachment of one or more dies die attach pads of the leadframe.

FIG. 6D is a top view of the electronic device of FIG. 6C after attachment of wire bonds from the one or more dies to the substrate assembly and to inner leads of the leadframe.

FIG. 6E illustrates a top view of the electronic device of FIG. 6D after undergoing formation of a mold compound.

### DETAILED DESCRIPTION

Leaded or leadless integrated circuit (IC) packages (e.g., SOIC, LGA, QFN, etc.) may include integrated isolation components (e.g., transformers, capacitors, filters, etc.) to create multi-chip modules (MCM's). MCM's include multiple dies and multiple integrated isolation components. The integrated isolation components are fabricated using a multiple layer (e.g., 6-layer) laminate topology. The multiple layer laminate configuration provides sufficient power transfer while simultaneously providing the required isolation. The multiple layer laminate configuration, however, significantly contributes to the overall package size and cost. Since reducing package size and cost are ongoing objectives in IC package designs, the multiple layer laminate configuration adversely affects these objectives.

Disclosed herein is a leadframe-based isolation component configuration for integration in leaded or leadless IC packages that overcome the aforementioned disadvantages. The leadframe-based isolation component can be fabricated using various leadframe-based processes (e.g., routable leadframe process, molded interconnect substrate process, embedded trace substrate process, etc.) to fabricate the isolation component in a dielectric layer (e.g., Ajinomoto Build-up Film (ABF)). The isolation component is then attached to a leadframe and further processed to form the IC package. The configuration of the leadframe-based isolation component can be customized for optimal power or signal transfer based on the application of the IC package. For example, a thickness of the component (i.e., a thickness of the metal layer (e.g., copper layer) comprising the component) can be adjusted as needed to reduce parasitic effects in the IC package. In addition, a thickness of the dielectric layer can vary to customize component parameters (e.g., efficiency, quality factor, mutual coupling co-efficient, etc.) while providing the required isolation. The isolation component can be comprised of multiple layers based on the application of the IC package.

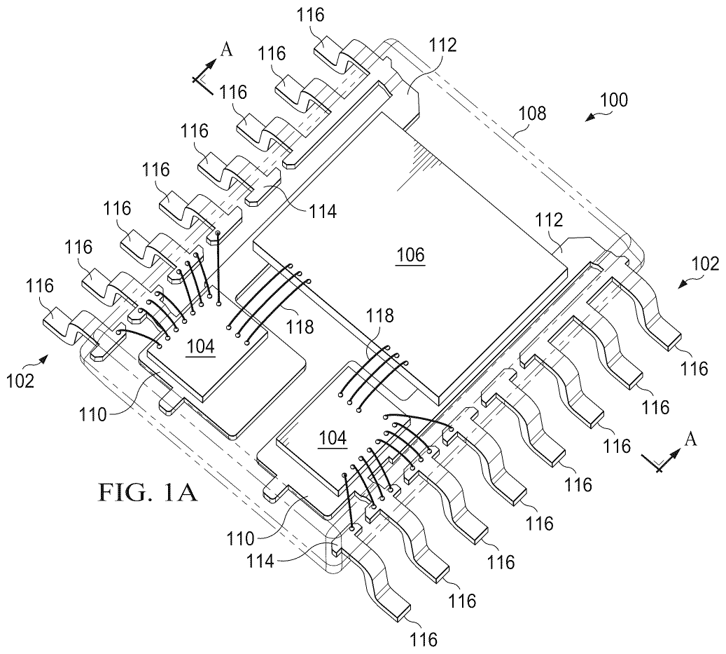

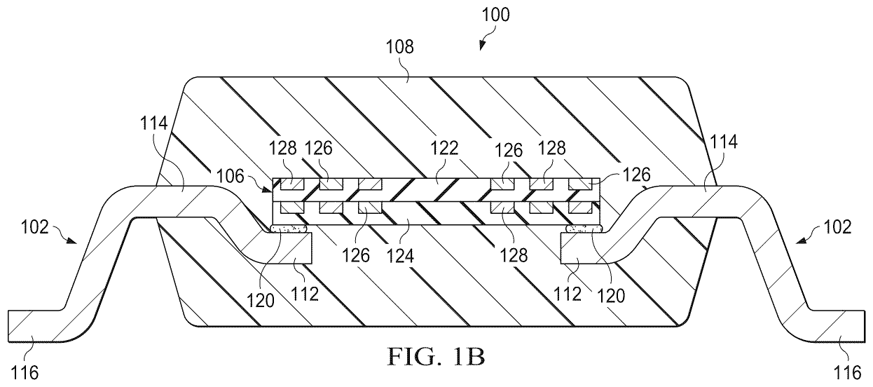

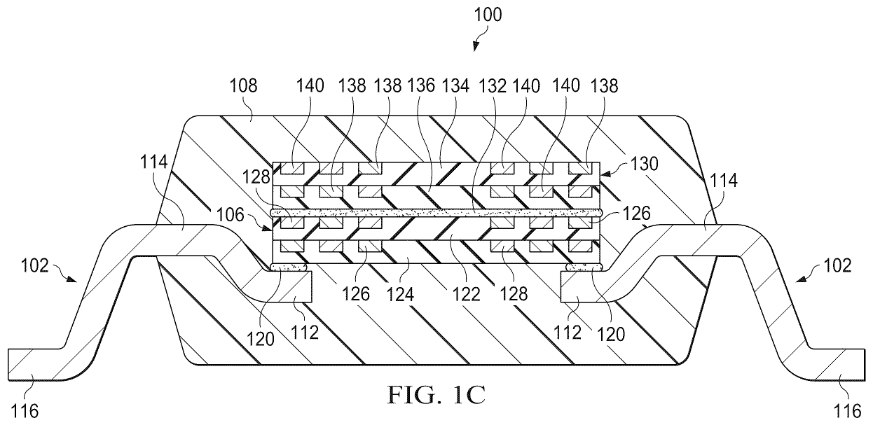

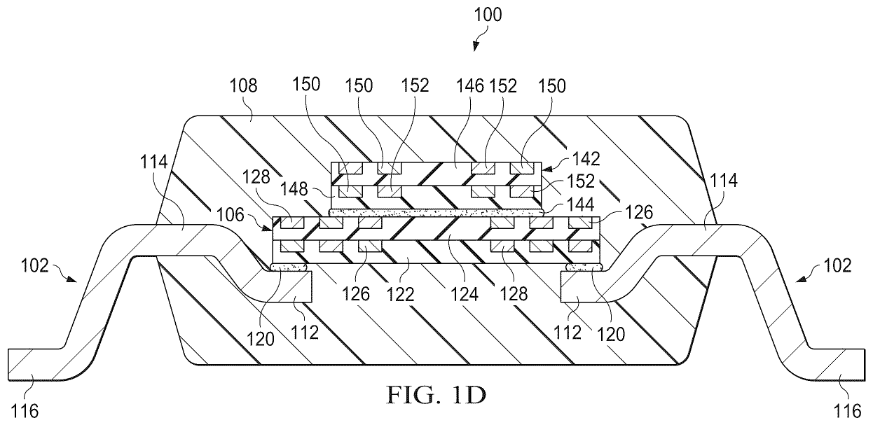

FIG. 1A is a perspective view of an example electronic device (e.g., integrated circuit (IC)) 100. FIG. 1B is a cross-sectional view of the electronic device of FIG. 1A taken along the line A-A. Although, the example electronic device 100 described herein and illustrated in FIGS. 1A and 1B is a leaded package, the electronic device 100 can be comprised of any type of leaded IC package (e.g., SOIC) or a non-leaded IC package including, but not limited to a land grid array (LGA), a quad-flat package (QFP), a quad-flat no-lead (QFN), etc. Thus, the example electronic device 100 illustrated in FIGS. 1A and 1B is for illustrative purposes only and is not intended to limit the scope of the invention. The electronic device 100 includes a leadframe 102, one or more dies 104 attached to the leadframe 102, one or more substrate assemblies 106 attached to the leadframe 102, and a mold compound 108.

The leadframe 102 includes die attach pads 110, contact pads 112, inner leads 114, and outer leads 116. The die attach pads 110 are configured to receive the one of more dies 104 and the contact pads 112 are configured to receive the substrate assembly 106. Wire bonds 118 provide electrical connections between the dies 104, the substrate assembly 106, and the inner leads 114. The mold compound 108 encapsulates the one or more dies 104, the substrate assembly 106, the die attach pads 110, the contact pads 112, the inner leads 114, and the wire bonds 118.

The substrate assembly 106 attaches to the contact pads 112 of the leadframe 102 via a die attach material (e.g., epoxy) 120 (see FIG. 1B). The substrate assembly 106 is comprised of a substrate (e.g., a dielectric such as but not limited to Epoxy, Ajinomoto Build-up Film (ABF), or Bismaleimide Triazine (BT)) comprised of a first substrate (dielectric) layer 122 and a second substrate (dielectric) layer 124. Each substrate layer 122, 124 can range in thickness from approximately 35-100 microns and can have the same thickness or different thicknesses. The substrate assembly 106 further includes one or more components (e.g., transformer, capacitor, filter, etc.). In the illustrated example, the one or more components is comprised of a first component 126 and a second component 128 fabricated from a metal (e.g., copper). It is to be understood, however, that the substrate assembly 106 can include more than two components. The number of components is based on the application of the electronic device 100. A thickness of the first and second components 126, 128 can range from 30-70 microns.

For simplicity, the example electronic device 100 illustrated in FIGS. 1A and 1B includes a single substrate assembly 106. It is to be understood, however, that additional substrate assemblies can be added to the electronic device 100 such that the additional substrate assemblies are arranged in a stacked formation on the substrate assembly 106 illustrated in FIG. 1B.

For example, FIG. 1C illustrates an additional (second) substrate assembly 130 attached to the substrate assembly 106 via a die attach material (e.g., epoxy) 132. The additional substrate assembly 130 is comprised of a substrate (e.g., a dielectric such as but not limited to Epoxy, Ajinomoto Build-up Film (ABF), or Bismaleimide Triazine (BT)) comprised of a first substrate (dielectric) layer 134 and a second substrate (dielectric) layer 136. Each substrate layer 134, 136 can range in thickness from approximately 35-100 microns. The substrate assembly 130 further includes one or more components (e.g., transformer, capacitor, filter, etc.). In the illustrated example, the one or more components is comprised of a first component 138 and a second component 140 fabricated from a metal (e.g., copper). It is to be understood, however, that the substrate assembly 130 can include more than two components. The number of components is based on the application of the electronic device 100. A thickness of the first and second components 138, 140 can range from 30-70 microns.

If an example where the first and second components 126, 128 of the substrate assembly 106 and the first and second components 138, 140 of the additional substrate assembly 130 are comprised of first, second, third, and fourth transformers, the addition of the second substrate assembly 130 increases the inductance of the electronic device 100.

FIG. 1D illustrates another example where a communication substrate assembly 142 is attached to the first substrate assembly 106 via a die attach material (e.g., epoxy) 144. The communication substrate assembly 142 is comprised of a substrate (e.g., a dielectric such as but not limited to Epoxy, Ajinomoto Build-up Film (ABF), or Bismaleimide Triazine (BT)) comprised of a first substrate (dielectric) layer 146 and a second substrate (dielectric) layer 148. Each substrate layer 146, 148 can range in thickness from approximately 35-100 microns. The substrate assembly 142 further includes one or more components (e.g., transformer, capacitor, filter, etc.). In the illustrated example, the one or more components is comprised of a first component 150 and a second component 152 fabricated from a metal (e.g., copper). It is to be understood, however, that the substrate assembly 142 can include more than two components. The number of components is based on the application of the electronic device 100. A thickness of the first and second components 150, 152 can range from 30-70 microns.

In an example where the first and second components 126, 128 of the substrate assembly 106 and the first and second components 150, 152 of the additional substrate assembly 142 are comprised of first, second, third, and fourth transformers, the addition of the communication substrate assembly 142 creates a stacked power and communication transformer device that can replace costly silicon based communication transformers.

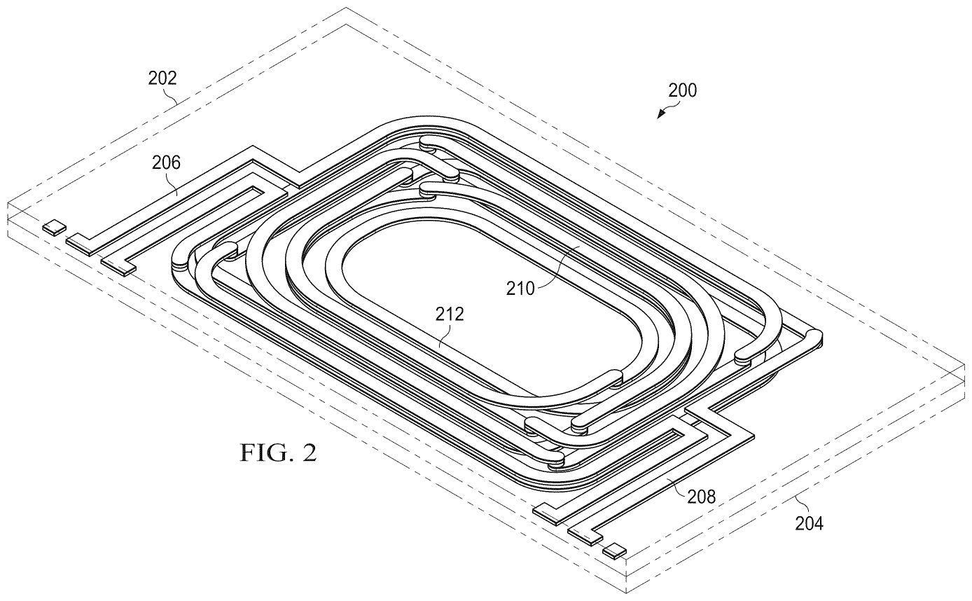

FIG. 2 is a perspective view of an example substrate assembly 200. The substrate assembly 200 is similar to the substrate assembly 106 illustrated in FIGS. 1A and 1B. Thus, reference is to be made to the examples of FIGS. 1A and 1B in the following description of the example in FIG. 2. The substrate assembly 200 is comprised of a first substrate (dielectric) layer 202 and a second substrate (dielectric) layer 204. As mentioned above, a thickness of each substrate layer 202, 204 can range from approximately 35-100 microns. The substrate assembly further includes a first component 206 and a second component 208. It is to be understood, however, that the substrate assembly 200 can include more than two components. The number of components is based on the application of the electronic device 100 illustrated in FIGS. 1A and 1B. A thickness of the first and second components 206, 208 can range from 30-70 microns.

In the example illustrated in FIG. 2, the first and second components 206, 208 are comprised of first and second transformers that include one or more coils 210, 212. The components, however, can be comprised of other electronic or electrical devices such as capacitors, filters, etc. Thus, the example illustrated in FIG. 2 is for illustrative purposes only and is not intended to limit the scope of the invention. The first and second transformers 206, 208 are made of metal (e.g., copper) and are fabricated using routable the leadframe-based process. The leadframe-based process facilitates the design, configuration, and fabrication of the first and second transformers 206, 208. For example, as illustrated in FIG. 2, but more clearly illustrated in FIG. 1B, both the first and second transformers 206, 208 (first and second components 126, 128 in FIG. 1B) can occupy both the first substrate layer 202 (122 in FIG. 1B) and the second substrate layer 204 (124 in FIG. 1B). This is accomplished by making connections though vias formed in the substrate assembly 200 thus allowing coils of the first and second transformers 206, 208 to cross between the first and second substrate layers 202, 204. Therefore, in one example, the first and second transformers 206, 208 can be interdigitated between the first and second substrate layers 202, 204. In another example, the first and second transformers 206, 208 are not interdigitated. In other words, the first transformer 206 can occupy only the first substrate layer 202 and the second transformer 208 can occupy only the second substrate layer 204.

In addition, leadframe-based technology facilitates custom design and fabrication of the first and second transformers 206, 208 to meet the transformer specifications based on the application of the electronic device 100. Specifically, the transformers first and second 206, 208 can be designed and configured to have any thickness, any number of coils, any inductance, a specific Q-factor, etc. Further, the first and second transformers 206, 208 can be configured in the first and second substrate layers 202, 204 to a certain distance from each other and to be isolated from other components and a leadframe of the electronic device 100. Still further, the first and second transformers 206, 208, more specifically, any component can be customized for optimal power or signal transfer based on the application of the electronic device. Simultaneously, the first and second substrate layers 202, 204 are designed to provide the required isolation to isolate the first and second transformers 206, 208 from other components (e.g., dies, capacitors, etc.) in the electronic device 100.

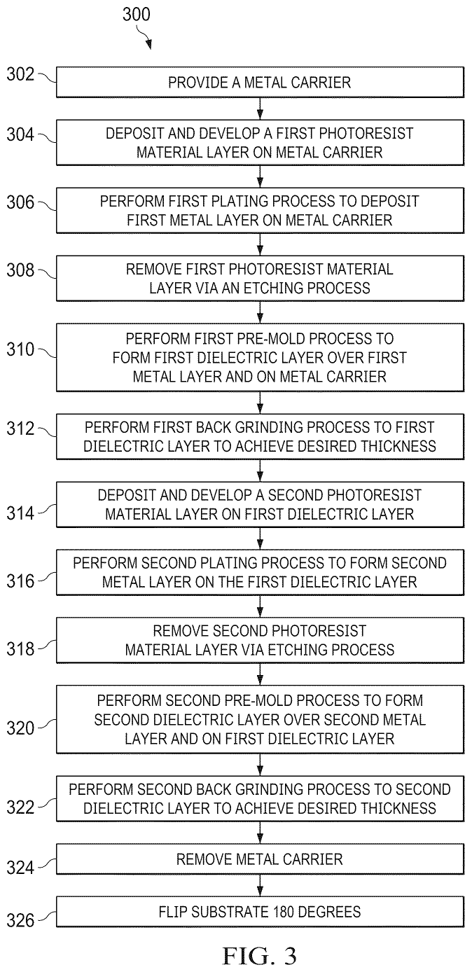

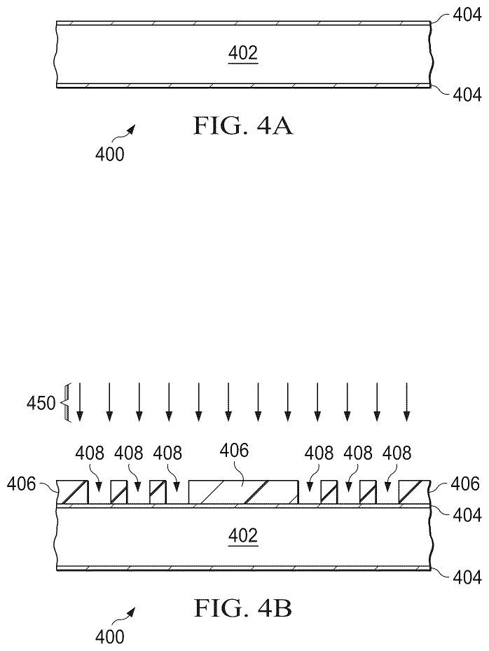

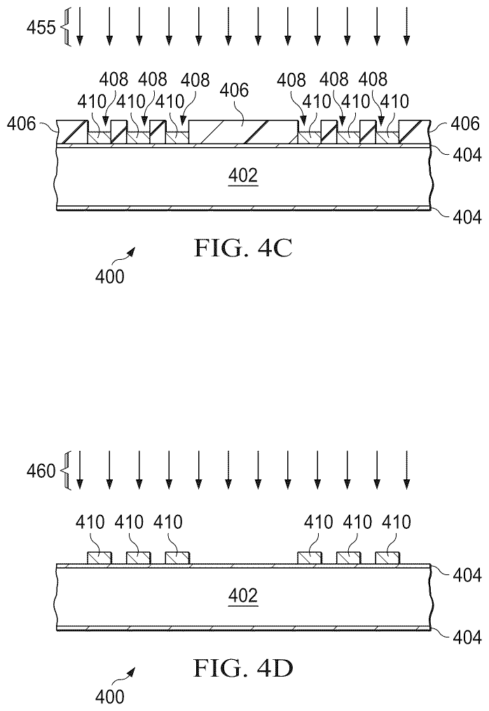

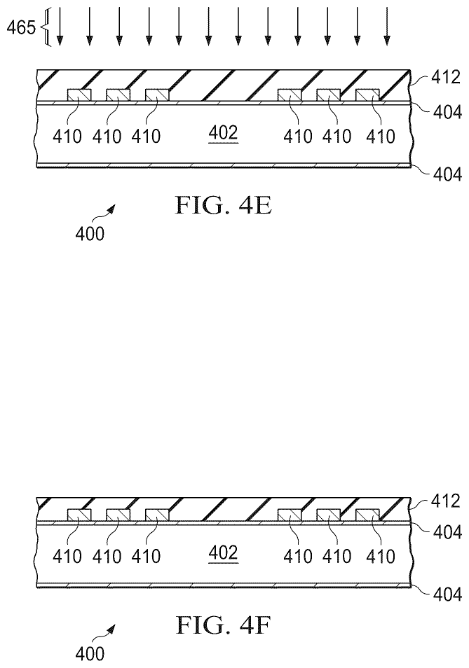

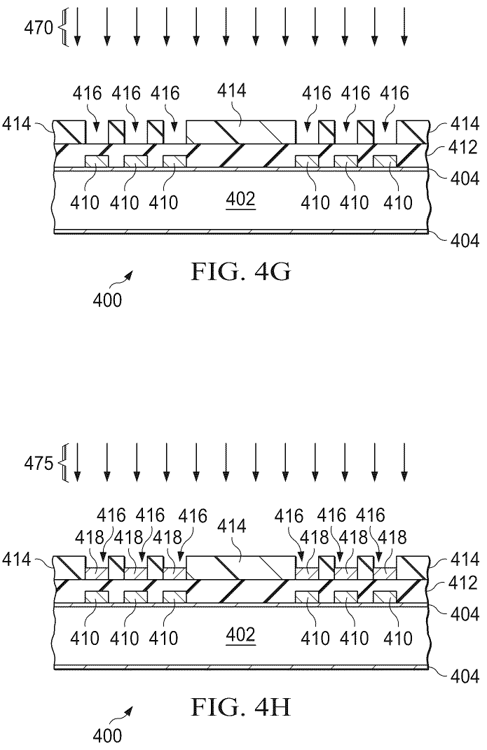

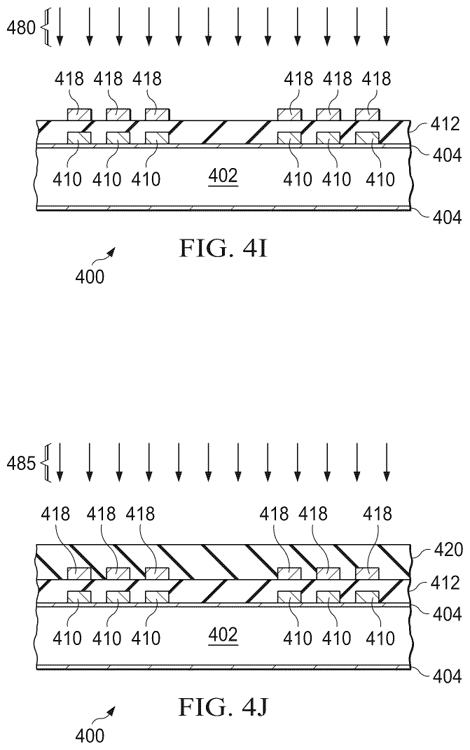

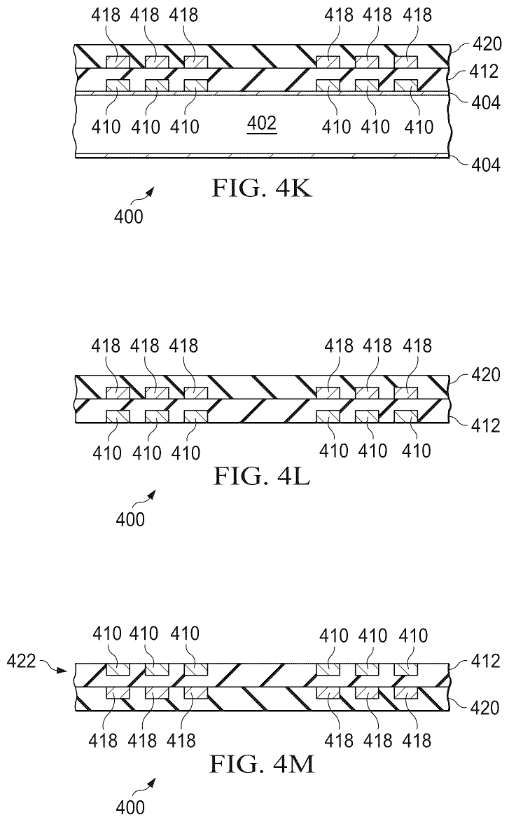

FIG. 3 is a block diagram flow chart explaining an example fabrication process 300 and FIGS. 4A-4M illustrate the example fabrication process 400 associated with the formation of an example substrate assembly. Though depicted sequentially as a matter of convenience, at least some of the actions shown can be performed in a different order and/or performed in parallel. Alternatively, some implementations may perform only some of the actions shown. Still further, although the example illustrated in FIGS. 3 and 4A-4M is an example method, other methods and configurations are possible. It is understood that although the method illustrated in FIGS. 3 and 4A-4M depicts the fabrication process of a single substrate assembly, the process applies to an array of substrate assemblies. Thus, after fabrication of the array of substrate assemblies the array is singulated to separate each substrate assembly from the array.

Referring to FIG. 3 and to FIGS. 4A-4M, the fabrication process 300 of the substrate assembly begins at 302 with a metal carrier (e.g., stainless steel) 402. The metal carrier 402 may include a carrier metal layer (e.g., copper) 404 deposited on one or both surfaces (e.g., top and bottom) of the metal carrier 402. At 304, a first photoresist material layer 406 overlies the metal carrier 402 and is patterned and developed to expose first openings 408 in the first photoresist material layer 406 over the metal carrier 402, resulting in the configuration of FIG. 4B. The first photoresist material layer 406 can have a thickness that varies in correspondence with the wavelength of radiation used to pattern the first photoresist material layer 406. The first photoresist material layer 406 may be formed over the metal carrier 402 via spin-coating or spin casting deposition techniques, selectively irradiated (e.g., via deep ultraviolet (DUV) irradiation) and developed to form the first openings 408.

At 306, the configuration of FIG. 4B undergoes a first electroplating process 450 to deposit a first metal layer or metal traces (e.g. copper) 410 in the first openings 408 of the first photoresist material layer 406 and on the metal carrier 402 resulting in the configuration in FIG. 4C. At 308, the first photoresist material layer 406 is stripped via a first etching process 455 resulting in the configuration of FIG. 4D. At 310, the configuration of FIG. 4D undergoes a first pre-molding process 460 to form a first dielectric layer (e.g., ABF laminate) 412 over the first metal layer 410 via compression molding thereby encapsulating the first metal layer 410 resulting in the configuration of FIG. 4E. At 312, the configuration of FIG. 4E undergoes a first back grinding process 465 to remove a portion of the first dielectric layer 412 to achieve a desired thickness of the first dielectric layer 412 resulting in the configuration of FIG. 4F. In other examples, the first dielectric layer 412 may be ground down such that surfaces of the first metal layer 410 are exposed and flush with a surface of the first dielectric layer 412.

At 314, a second photoresist material layer 414 overlies the first dielectric layer 412 and is patterned and developed to expose second openings 416 in the second photoresist material layer 414 over the first dielectric layer 412, resulting in the configuration of FIG. 4G. The second photoresist material layer 414 can have a thickness that varies in correspondence with the wavelength of radiation used to pattern the second photoresist material layer 414. The second photoresist material layer 414 may be formed over the first dielectric layer 412 via spin-coating or spin casting deposition techniques, selectively irradiated (e.g., via deep ultraviolet (DUV) irradiation) and developed to form the second openings 416.

At 316, the configuration of FIG. 4G undergoes a second electroplating process 470 to deposit a second metal layer or metal traces (e.g. copper) 418 in the second openings 416 of the second photoresist material layer 414 and on the first dielectric layer 412 resulting in the configuration in FIG. 4H. At 318, the second photoresist material layer 414 is stripped via a second etching process 475 resulting in the configuration of FIG. 4I. At 320, the configuration of FIG. 4I undergoes a second pre-molding process 480 to form a second dielectric layer (e.g., ABF laminate) 420 over the first dielectric layer 412 via compression molding thereby encapsulating the second metal layer 418 resulting in the configuration of FIG. 4J. At 322, the configuration of FIG. 4J undergoes a second back grinding process 485 to remove a portion of the second dielectric layer 420 to achieve a desired thickness of the second dielectric layer 420 resulting in the configuration of FIG. 4K. At 324, the metal carrier 402 is removed resulting in the configuration of FIG. 4L. Specifically, the metal carrier is dislodged from the first and second dielectric layers 412, 420 via a chemical etch process and a mechanical process. At 326, the configuration of FIG. 4L is flipped 180° for mounting on a leadframe, as will be subsequently described, resulting in the substrate assembly 422 illustrated in FIG. 4M.

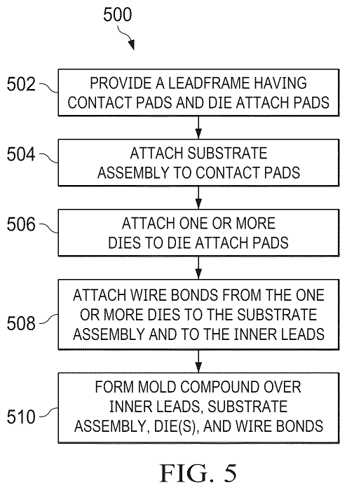

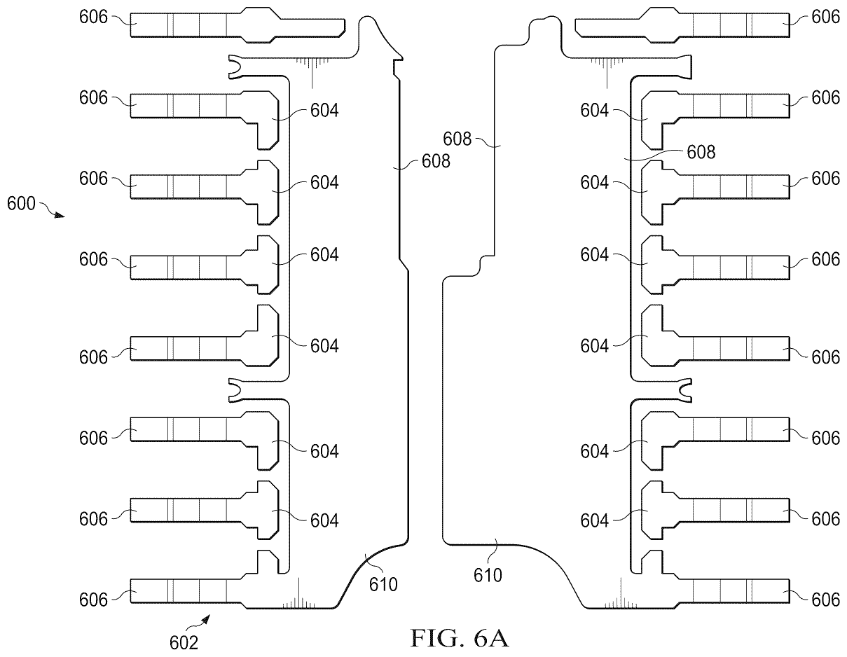

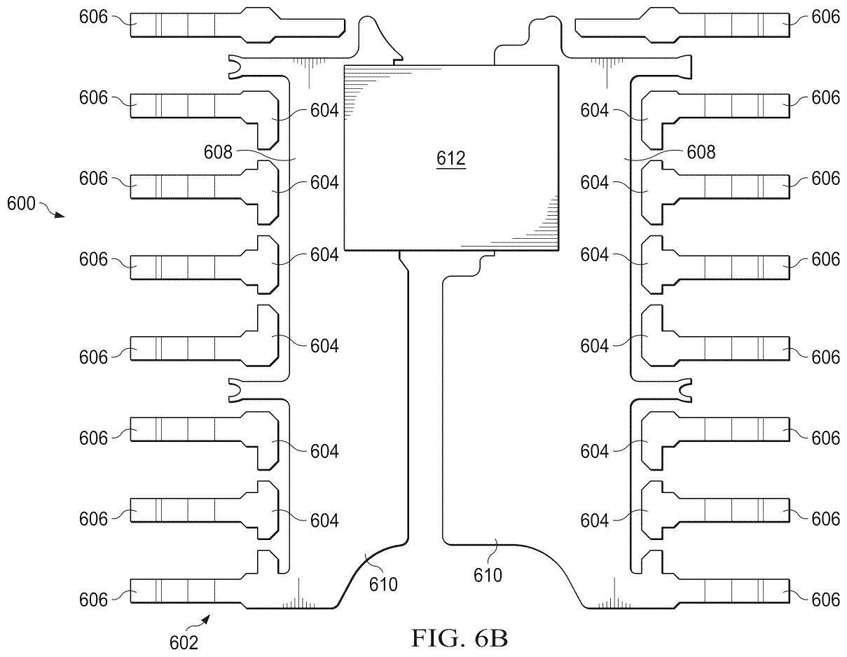

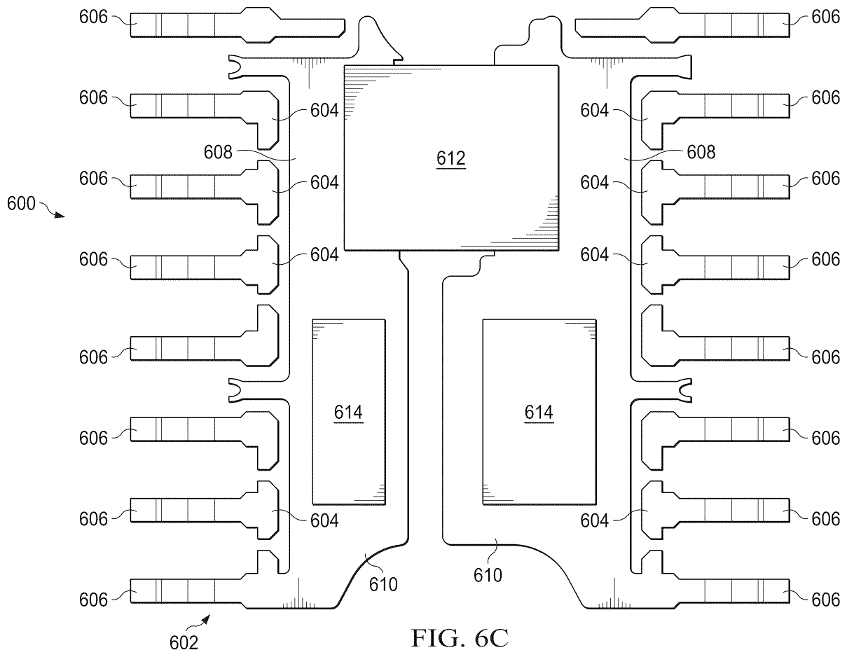

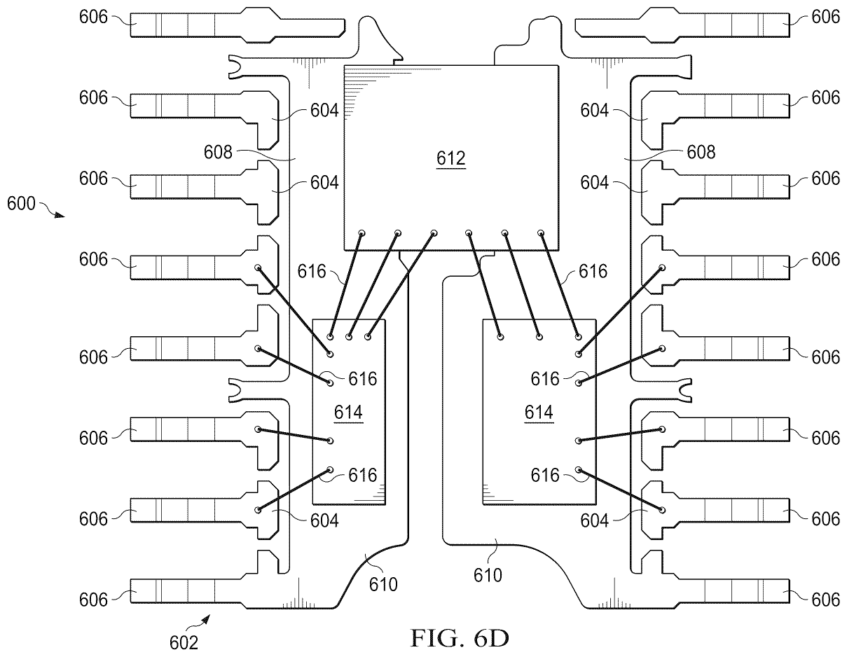

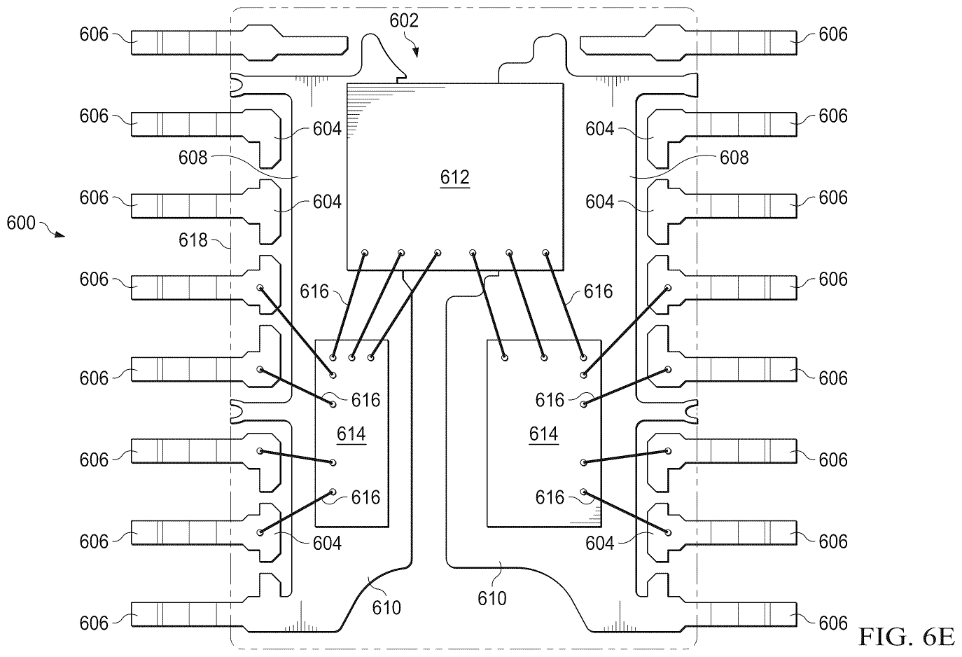

FIG. 5 is a block diagram flow chart explaining assembly steps 500 and FIGS. 6A-6E illustrate an assembly process 600 associated with the formation of an example electronic device similar to the electronic device 100 illustrated in FIG. 1A that includes an example substrate assembly similar to the substrate assembly illustrated in FIG. 4M. Though depicted sequentially as a matter of convenience, at least some of the actions shown can be performed in a different order and/or performed in parallel. Alternatively, some implementations may perform only some of the actions shown. Still further, although the example illustrated in FIGS. 5 and 6A-6E is an example method illustrating an example configuration, other methods and configurations are possible. It is understood that although the method illustrated in FIGS. 5 and 6A-6E depicts the fabrication process of a single electronic device, the process applies to an array of electronic devices. Thus, after fabrication of the array of electronic devices the array is singulated to separate each electronic device from the array.

Referring to FIG. 5 and to FIGS. 6A-6E, the assembly process 500 of the example electronic device begins at 502 with a leadframe 602. The leadframe 602 includes inner leads 604, outer leads 606, contact pads 608, and die attach pads 610. At 504, a substrate assembly 612 is attached to the contact pads 608 via a die attach material (e.g., epoxy 120, see FIG. 1B) resulting in the configuration of FIG. 6B. Although the example illustrated in FIGS. 6A-6E illustrates a single substrate assembly 612, it is to be understood that the example electronic device can include more than one substrate assembly 612. Thus, the example process illustrated in FIGS. 5 and 6A-6E is for illustrative purposes only and is not intended to limit the scope of the invention. At 506, One or more dies 614 are attached to the die attach pads 610 via the die attach material resulting in the configuration of FIG. 6C. At 508, interconnects (e.g., wire bonds) 616 are attached from the one or more dies 614 to the substrate assembly 612 and to the inner leads 604 of the leadframe 602 resulting in the configuration of FIG. 6D. In other examples, the one or more dies 614 may be comprised of flip chip dies where the flip chip dies are connected via conductive bump interconnects. In addition, the interconnects may be a combination of wire bonds, conductive bumps, solder, etc. At 510, a mold compound 618 is formed over and encapsulates the inner leads 604, the substrate assembly 612, the one or more dies 614, and the wire bonds 616 resulting in the configuration of FIG. 6E.

Described above are examples of the subject disclosure. It is, of course, not possible to describe every conceivable combination of components or methodologies for purposes of describing the subject disclosure, but one of ordinary skill in the art may recognize that many further combinations and permutations of the subject disclosure are possible. Accordingly, the subject disclosure is intended to embrace all such alterations, modifications and variations that fall within the spirit and scope of the appended claims. In addition, where the disclosure or claims recite “a,” “an,” “a first,” or “another” element, or the equivalent thereof, it should be interpreted to include one or more than one such element, neither requiring nor excluding two or more such elements. Furthermore, to the extent that the term “includes” is used in either the detailed description or the claims, such term is intended to be inclusive in a manner similar to the term “comprising” as “comprising” is interpreted when employed as a transitional word in a claim. Finally, the term “based on” is interpreted to mean based at least in part.

What is claimed is:

1. An electronic device comprising:
a leadframe;
a substrate assembly attached to the leadframe, the substrate assembly including a first substrate layer and a second substrate layer;
an electronic component formed in at least one or both of the first substrate layer and the second substrate layer;
a die attached to the leadframe; and
a mold compound encapsulating the substrate assembly and the die.

2. The electronic device of claim 1, wherein the leadframe includes contact pads and wherein the substrate assembly attaches to the contact pads of the leadframe.

3. The electronic device of claim 1, wherein the leadframe includes die attach pads and wherein the die is attached to the die attach pad.

4. The electronic device of claim 1, wherein the electronic component is a first component, the electronic device further comprising a second electronic component.

5. The electronic device of claim 4, wherein the first electronic component is formed in both the first substrate layer and the second substrate layer.

6. The electronic device of claim 5, wherein the second electronic component is formed in both the first substrate layer and the second substrate layer and wherein the first electronic component and the second electronic component are interdigitated.

7. The electronic device of claim 6, wherein the first electronic component is a first transformer and the second electronic component is a second transformer.

8. The electronic device of claim 1 further comprising wire bonds that attach the die to the substrate assembly and attach the die to inner leads of the leadframe.

9. The electronic device of claim 1, wherein the substrate assembly is a first substrate assembly, the electronic device further comprising a second substrate assembly attached to the first substrate assembly.

10. A substrate assembly comprising:
a first substrate layer;
a second substrate layer attached to the first substrate layer;
a first electronic component formed in one or both of the first substrate layer and the second substrate layer; and
a second electronic component formed in one or both of the first substrate layer and the second substrate layer, wherein the first electronic component and the second electronic component are interdigitated.

11. The substrate assembly of claim 10, wherein the first electronic component is a first transformer and the second electronic component is a second transformer.

12. The substrate assembly of claim 11, wherein the first transformer includes coils formed in one or both of the first substrate layer and the second substrate layer and the second transformer includes coils formed in one or both of the first substrate layer and the second substrate layer.

13. The substrate assembly of claim 10, wherein the first substrate layer is a first dielectric layer and the second substrate layer is a second dielectric layer.

14. A method comprising:
depositing a first metal layer on a carrier;
forming a first dielectric layer over the first metal layer;
depositing a second metal layer on the first dielectric layer;
forming a second dielectric layer over the second metal layer; and
removing the first and second dielectric layers from the carrier.

15. The method of claim 14, wherein depositing a first metal layer on a carrier includes patterning a first photoresist material layer on the carrier to expose first openings in the first photoresist material layer and performing a first electroplating process to deposit the first metal layer in the first openings of the first photoresist material layer.

16. The method of claim 15, wherein forming a first dielectric layer over the first metal layer further includes performing a first back grinding process to the first dielectric layer to achieve a desired thickness.

17. The method of claim 16, wherein depositing a second metal layer on the first dielectric layer includes patterning a second photoresist material layer on the first dielectric layer to expose second openings in the second photoresist material layer and performing a second electroplating process to deposit the second metal layer in the second openings of the second photoresist material layer.

18. The method of claim 17, wherein forming a second dielectric layer over the second metal layer further includes performing a second back grinding process to the second dielectric layer to achieve a desired thickness.

19. The method of claim 18, wherein the thickness of the first dielectric layer is the same as the thickness of the second dielectric layer.

20. The method of claim 19, wherein the thickness of the first dielectric layer is different than the thickness of the second dielectric layer.

21. The method of claim 14, wherein removing the first and second dielectric layers from the carrier includes dislodging the carrier from the first and second dielectric layers via a chemical etch process and a mechanical process.

22. A method comprising:
attaching at least one substrate assembly to contact pads of a leadframe;
attaching at least one die to die attach pads of the leadframe;
attaching wire bonds from the at least one die to the at least one substrate assembly and to inner leads of the leadframe; and
forming a mold compound over the at least one substrate assembly, the at least one die, the wire bonds, and the inner leads.
